(19) United States
(12) Patent Application Publication
(10) Pub. No.: US 2008/0040920 A1
(43) Pub. Date: Feb. 21, 2008

(54) Printed wiring board having multiple instersitial resistors of different electrical resistance values and method of making the same

(75) Inventors: Andrew J. Brackenbury, Oro Valley, AZ (US); Lance A. Collier, Tucson, AZ (US); Larry L. Galey, Tucson, AZ (US); Nathan S. Moyer, Tucson, AZ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/506,707

(22) Filed: Aug. 18, 2006

(51) Int. Cl. H05K 1/03

(52) U.S. Cl. 29/832; 29/852; 174/255; 174/262

(57) ABSTRACT

A multi-stage masking and plating process for making printed wiring boards with multiple interstitial resistors includes disposing a first mask over a printed wiring board substrate that leaves one or more first vias of the plurality of vias exposed and covers the remaining vias. The first vias are filled with an electrically resistive compound to thereby form one or more first interstitial resistors. The first mask is removed, and a second mask is disposed over the printed wiring board substrate that leaves one or more second vias of the plurality of vias exposed and covers the remaining vias. The second vias are filled with an electrically resistive compound to thereby form one or more second interstitial resistors. The second mask is then removed.

### TECHNICAL FIELD

The present invention relates to printed wiring boards and, more particularly, to a method of making printed wiring boards with multiple interstitial resistors of different resistances.

### BACKGROUND

Printed wiring boards, which are also sometimes referred to as printed circuit boards, are used to mount various circuit components including, for example, integrated circuit components, and discrete analog and digital components. These components may additionally include both active and passive circuit components. In some instances, the active circuit components generate relatively high-speed signals, having relatively rapid rise and fall times.

The rise and fall times of the high-speed signals generated by active components continues to decrease. For example, some active components generate signals having rise and fall times in the sub-nanosecond range. Such relatively rapid rise and fall times may require the traces on the printed wiring boards on which the active components are mounted to be treated as transmission lines. To facilitate this, resistors may be mounted directly at the sources of these high-speed signals (e.g., at the output of the components generating these signals) to impedance match the source to the printed wiring board traces. In many instances, however, the space needed to include a sufficient number of resistors of different resistances on a printed wiring board may not be available.

Hence, there is a need for a method of manufacturing printed wiring board that includes sufficient numbers of resistors of different resistances thereon that will adequately impedance match high speed signal sources to printed wiring board traces. The present invention addresses at least this need.

### BRIEF SUMMARY

The present invention provides a multi-stage masking and plating process for making printed wiring boards with multiple interstitial resistors of different resistance values.

In one embodiment, and by way of example only, a method of forming a plurality of interstitial resistors in a printed wiring board substrate that has a plurality of vias formed at least partially therethrough includes the step of disposing a first mask over the printed wiring board substrate that leaves one or more first vias of the plurality of vias exposed and covers the remaining vias. The first vias are filled with an electrically resistive compound to thereby form one or more first interstitial resistors. Each first interstitial resistor has a first electrical resistance value. The first mask is removed, and a second mask is disposed over the printed wiring board substrate that leaves one or more second vias of the plurality of vias exposed and covers the remaining vias. The second vias are filled with an electrically resistive compound to thereby form one or more second interstitial resistors. Each second interstitial resistor has a second electrical resistance value that differs from the first electrical resistance value. The second mask is removed.

In another exemplary embodiment, a method of manufacturing a multi-laminate printed wiring board substrate assembly includes the step of providing a first printed wiring board substrate having a plurality of vias formed at least partially therethrough. A first mask is disposed over the first printed wiring board substrate that leaves one or more first vias of the plurality of vias exposed and covers the remaining vias. The first vias are filled with an electrically resistive compound to thereby form one or more first interstitial resistors, each having a first electrical resistance value. The first mask is removed, and a second mask is disposed over the first printed wiring board substrate that leaves one or more second vias of the plurality of vias exposed and covers the remaining vias. The second vias are filled with an electrically resistive compound to thereby form one or more second interstitial resistors, each having a second electrical resistance value that differs from the first electrical resistance value. A conductive material is deposited over at least the second vias, and the second mask is removed. A second printed wiring board substrate having a plurality of vias formed at least partially therethrough is provided. A third mask is disposed over the second printed wiring board substrate that leaves one or more third vias of the plurality of vias exposed and covers the remaining vias. The third vias are filled with an electrically resistive compound to thereby form one or more third interstitial resistors, each having a third electrical resistance value. The third mask is removed. The first printed wiring board substrate is joined to the second printed wiring board substrate to form a multi-laminate wiring board substrate assembly.

Other independent features and advantages of the preferred printed wiring board manufacturing methods will become apparent from the following detailed description, taken in conjunction with the accompanying drawings which illustrate, by way of example, the principles of the invention.

### BRIEF DESCRIPTION OF THE DRAWINGS

FIG. 1 is a simplified cross section view of an exemplary printed wiring board that may be manufactured according to an embodiment of the present invention;

FIGS. 2-8 depict a process for manufacturing an exemplary printed wiring board according to an embodiment of the present invention; and

FIG. 9 depicts a simplified cross section view of an exemplary multi-laminate printed wiring board that may be manufactured according to an embodiment of the present invention.

### DETAILED DESCRIPTION OF A PREFERRED EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

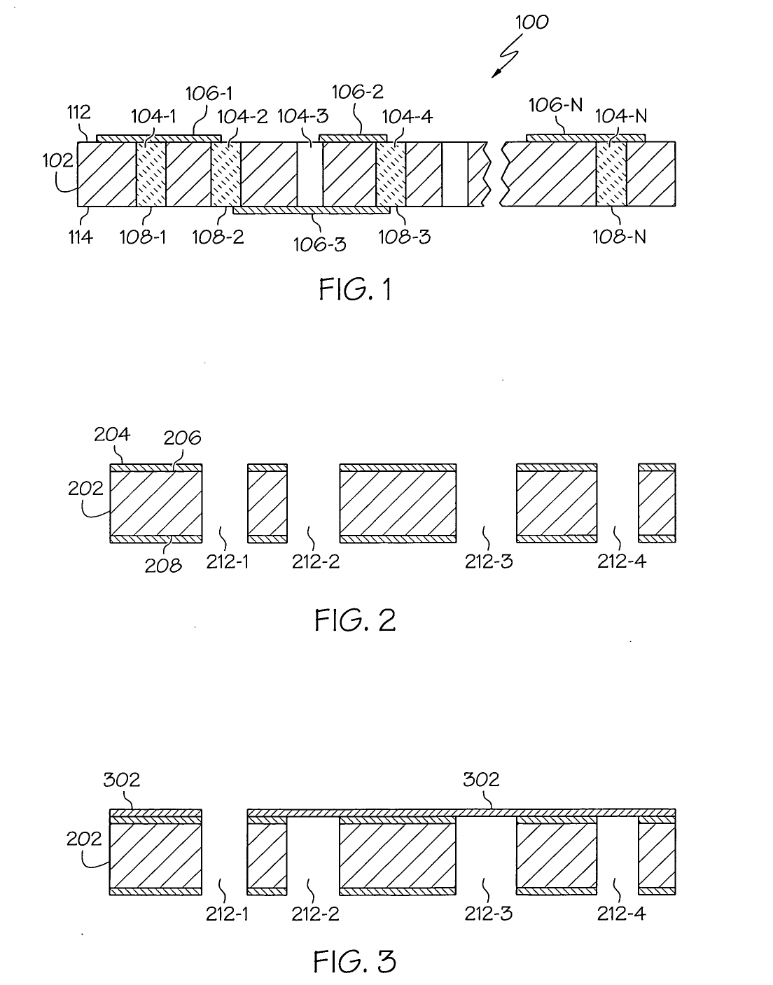

Turning now to FIG. 1, a cross section view of a portion of a printed wiring board (PWB) 100 is depicted. The PWB 100 includes a substrate 102, a plurality of vias 104 (e.g., 104-1, 104-2, 104-3, . . . 104-N) formed at least partially through the substrate 102, a plurality of conductive traces 106 (e.g., 106-1, 106-2, 106-3, . . . 106-N), and a plurality of interstitial resistors 108 (e.g., 108-1, 108-2, 108-3, . . . 108-N). The substrate 102 is substantially planar, having a first side 112 and a second side 114, and may be constructed of any one of numerous materials. For example, the substrate 102 may be constructed of a fiberglass-resin, a glass/epoxy, a heat-resistant resin, paper/phenol, or phenolic, just to name a few examples. Moreover, although the substrate 100 in the depicted embodiment is a double-sided, single laminate substrate, it will be appreciated that single-sided, single laminate substrates, and multi-laminate substrates could also be used.

In the depicted embodiment, the vias 104 are formed through the substrate 102, and thus extend between the substrate first and second sides 112, 114. It will be appreciated, however, that in alternative embodiments, one or more of the vias 104 may be formed only partially through the substrate 102. For example, in embodiments in which the substrate 102 is implemented using a multi-laminate substrate, one or more of the vias 104 may extend through only one or more of the laminates that comprise the substrate 102.

The conductive traces 106, as is generally known, are used to electrically interconnect non-illustrated components that may be mounted on the substrate 102, to electrically interconnect the interstitial resistors 108 to one or more of the non-illustrated components and/or other interstitial resistors, and to electrically interconnect the substrate 102 to one or more external circuits and/or devices. The conductive traces 108 are preferably formed of a relatively low resistance conductive material, such as copper. It will be appreciated, however, that various other conductive materials may also be used.

The interstitial resistors 108 are disposed in at least selected ones of the plurality of vias 104, and are formed of an electrically resistive material or compound. The interstitial resistors 108 each have an electrical resistance value, and its particular resistance value depends on various factors. For example, the electrical resistance value of each interstitial resistor 108 may vary with the type of resistive compound that is used, with the length of the resistor 108, and with the cross sectional area of the resistor 108. In particular, various known resistive compounds have differing values of resistivity. For example, known carbon-based resistive inks are available in different mixtures that provide different ranges of resistance. Moreover, for a given resistive compound, it is generally known that the resistance of an interstitial resistor 108 is proportional to its length, and inversely proportional to its cross sectional area.

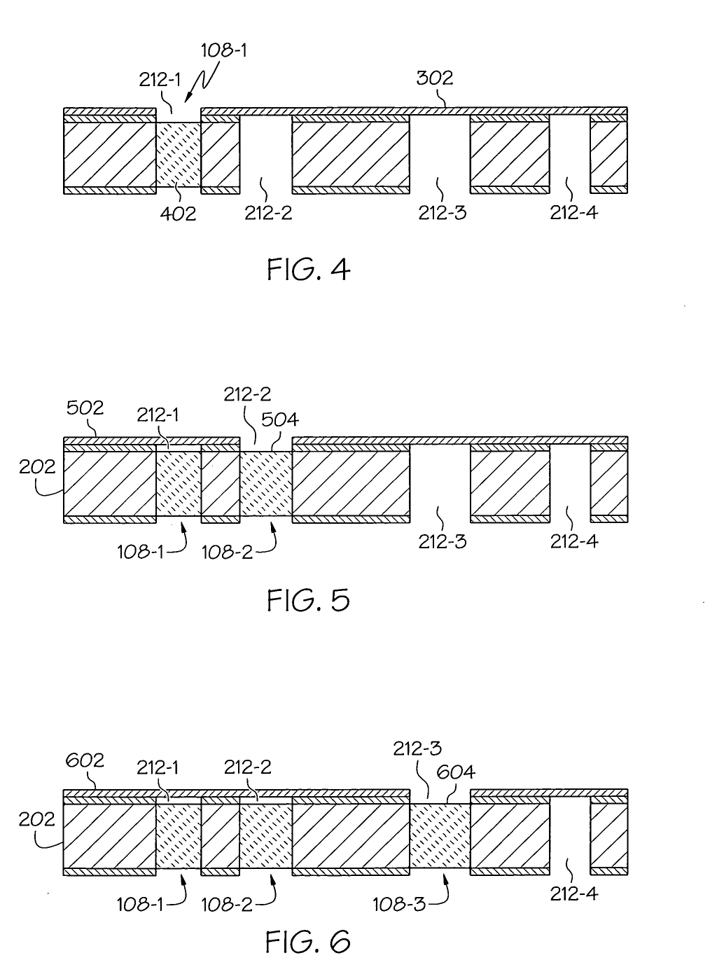

In addition to the above, it is noted that resistance values of at least two of the interstitial resistors 108 depicted in FIG. 1 differ from one another. A particular preferred method of forming a plurality of interstitial resistors 108 of different resistance values in the PWB substrate 102 will now be described. In doing so, reference should be made to FIGS. 2-8.

As shown in FIG. 2, a PWB substrate 202 is first provided. In the depicted embodiment, the substrate 202 is a double-sided, single laminate substrate having conductive foil layers 204 disposed on its first and second sides 206, 208. It will be appreciated, as noted above, that the substrate 202 and conductive foil layers 204 may be constructed of any one of numerous suitable materials. As FIG. 2 additionally shows, a plurality of vias 212 (e.g., 212-1, 212-2, 212-3, 212-4) are formed through the substrate 202 and through each of the conductive foil layers 204. For clarity and ease of illustration, only four vias 212 are shown as being formed through the substrate 202. It will be appreciated, however, that more or less than this number of vias 212 could be formed in the substrate 202. Moreover, although the vias 212 could be formed using any one of numerous processes and devices, each via is preferably formed at its position using a mechanical drill, such as a computer numerical control (CNC) drill.

After the vias 212 are formed, and depending on the process and/or device that is used to form the vias 212, one or more post-formation processes could be conducted. For example, the via 212 formation process could result in burrs being formed on the foil layers 204, and dust adhering to the foil layers 204 and/or walls of the vias 212. If so, a deburring and/or dust removal process may be conducted. In addition, if the vias 212 are formed using a drill, heat generated during the drilling process may cause some localized melting of the substrate 202 and form a so-called smear on walls of the vias 212. Thus, a de-smear process may also be conducted to remove the smear.

Whether or not one or more of the above-described post-via-formation processes (or additional processes) is conducted, at least selected ones of the vias 212 are then filled with a resistive compound. Not all of the vias 212 on the substrate 202 may be filled with a resistive compound, and those vias 212 that are filled with a resistive compound are not filled simultaneously. Rather, those vias 212 that are being used to implement interstitial resistors having equal, or at least substantially equal, resistance values are preferably filled simultaneously, while the remaining vias 212 are prevented from being filled. To accomplish this, a multi-stage masking process, which will now be described in more detail, is implemented. Before describing the process, it is noted that, once again for clarity and ease of depiction and description, in the depicted embodiment the first via 212-1 is being used to implement a first interstitial resistor having a first resistance value, the second via 212-2 is being used to implement a second interstitial resistor having a second resistance value that differs from the first, the third via 212-3 is being used to implement a third interstitial resistor having a third resistance value that differs from the first and second, and the fourth via 212-4 is not being used to implement an interstitial resistor.

Turning now to FIG. 3, it is seen that a first mask 302 is disposed onto at least the substrate first side 206. The first mask 302 is configured such that it covers the second, third, and fourth vias 212-2, 212-3, 212-4, but leaves the first via 212-1 exposed. It will be appreciated that the first mask 302 may be implemented using any one of numerous types of suitable masking materials. Preferably, the masking material that is used is compatible with the resistive compound. No matter the specific type of masking material that is used, after the first mask 302 is properly positioned, the first via 212-1 is filled with a resistive compound 402 that will implement an interstitial resistor 108-1 having the first resistance value. The first mask 302 is then removed and the resistive compound 402 is suitably cured to form the interstitial resistor 108-1. It will be appreciated that the resistive compound 402 could be any one of numerous types of suitable resistive compounds, now known or developed in the future. In the depicted embodiment, however, the resistive compound is a carbon-based ink. It will additionally be appreciated that the resistive compound 402 may be disposed in the first via 212-1 using any one of numerous processes and devices, including a press, a squeegee, a vacuum, or various other suitable processes, devices, or combinations thereof. It will additionally be appreciated that the curing process may vary depending on the particular resistive compound 402 that is used, as is generally known. Preferably, the disposition and curing processes that are used are suitably conducted and controlled to eliminate, or at least substantially eliminate, voids and/or gas bubbles from the resistive compound 402.

Before proceeding further, it is noted that although only one via 212 is used to implement an interstitial resistor 108-1 having the first resistance value, if two or more vias 212 were being used to implement interstitial resistors 108-1 having the first resistance value, then the first mask 302 would be configured such that two or more vias 212 were exposed and could be filled with the resistive compound 402. Moreover, if one or more other vias 212 that are to be used to implement interstitial resistors have diameters that differ from the first via 212-1 and, if filling these larger diameter vias 212 with the resistive compound 402 would result in these larger diameter vias 212 implementing interstitial resistors 108 of desired resistance values, the first mask 302 could additionally be configured such that these larger diameter vias 212 would remain exposed.

Returning now to the description, and with reference now to FIG. 5, after the resistive compound 402 is disposed in the first via 212-1 and cured, a second mask 502 is disposed onto at least the substrate first surface 204. The second mask 502 is configured such that it covers the first, third, and fourth vias 212-1, 212-3, 212-4, but leaves the second via 212-2 exposed. The second via 212-2 is then filled with a resistive compound 504 that will implement an interstitial resistor 108-2 having the second resistance value. The second mask 502 is then removed, and the resistive compound is cured. As with the first resistance value, if two or more vias 212 were being used to implement interstitial resistors 108-2 having the second resistance value, or if filling one or more larger diameter vias 212 with the resistance compound 504 would implement desired resistance values, then the second mask 502 would be configured such that two or more vias 212 were exposed and could be filled with the appropriate resistive compound 504.

Thereafter, and as FIG. 6 depicts, a third mask 602 is disposed onto at least the substrate first surface 204. The third mask 602 is configured such that it covers the first, second, and fourth vias 212-1, 212-2, 212-4, but leaves the third via 212-3 exposed. The third via 212-3 is then filled with a resistive compound 604 that will implement an interstitial resistor 108-3 having the third resistance value. The third mask 602 is then removed, and the resistive compound is cured. As with the first and second resistance values, if two or more vias 212 were being used to implement interstitial resistors 108-3 having the third resistance value, or if filling one or more larger diameter vias 212 with the resistance compound 604 would implement desired resistance values, then the third mask 602 would be configured such that two or more vias 212 were exposed and could be filled with the appropriate resistive compound 604.

After all of the interstitial resistors 108 have been appropriately formed, the associated vias 212 are cap-plated with an appropriate plating material. It will be appreciated that the plating material may be any one of numerous types of suitable conductive materials, non-limiting examples of which include copper, tin, various copper-tin alloys, various nickel alloys, and various silver alloys, and gold. In some embodiments it may be desirable to cap-plate one or more other vias 212 in addition to those associated with the interstitial resistors 108. Preferably, and as shown in FIG. 7, masks 702 are disposed onto the substrate first and second surfaces 206. The masks 702 cover those vias 212 that are not to be cap-plated, and leave those vias 212 that are to be cap-plated exposed. In the depicted embodiment, the first, second, and third vias 212-1, 212-2,,and 212-3 are exposed, whereas the fourth via is covered. Thereafter, and as shown in FIG. 8, the first, second, and third vias 212-1, 212-2, and 212-3 are cap-plated with a suitable plating material 802, and the masks 702 are removed.

After the vias 212 have been cap-plated and the masks 702 removed from the substrate 202, circuit traces are then formed in one or both (preferably both) conductive foil layers 204. The circuit traces may be formed using any one of numerous known processes. Such processes include, for example, the use of photoresist masks and etchant, as is generally known in the art. It is noted that before the circuit traces are formed, a planarization process is preferably performed to provide smooth, even surfaces, which in turn provides for uniform etching to form the traces. After the circuit traces are formed, the circuit traces and cap-plated vias 212 may additionally be plated with a non-illustrated protective plating material, such as immersion gold or other non-corrosive metal.

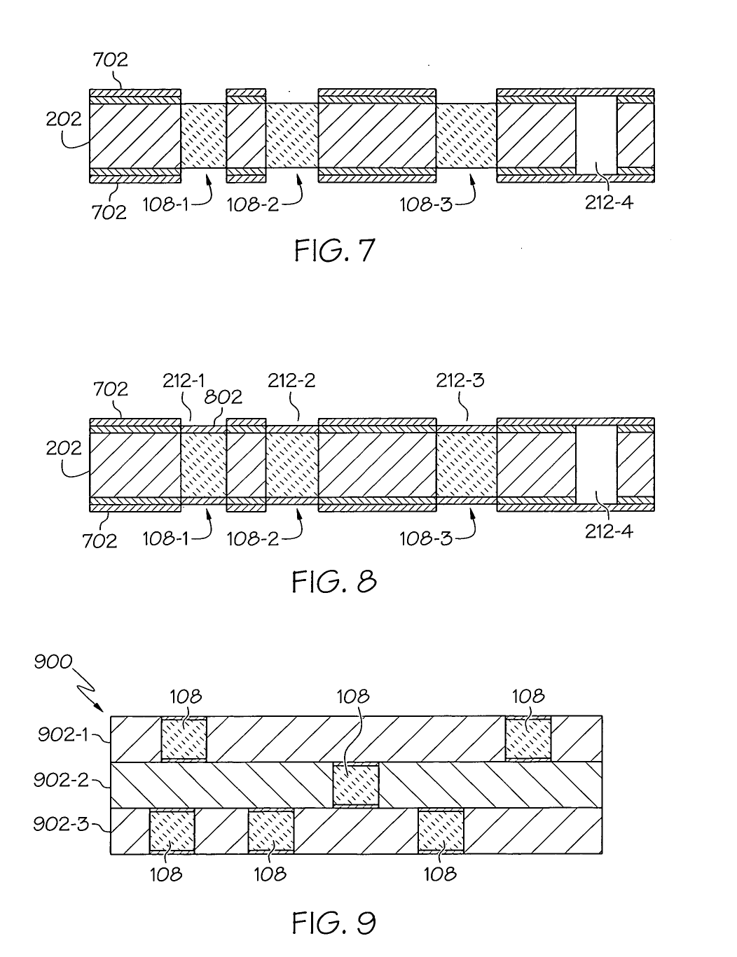

It will be appreciated that the process described above can be used in the manufacture of a multi-laminate PWB 900, such as the one depicted in FIG. 9. In particular, each of the individual substrates 902-1, 902-2, 902-3 that comprise the multi-laminate PWB 900, and that include one or more interstitial resistors 108, can undergo the above-described process to implement the desired number and resistance of interstitial resistors 108. The individual substrates 902-1, 902-2, 902-3, may then be joined to form the multi-laminate PWB 900. It will be appreciated that although the depicted multi-laminate PWB 900 includes three substrates 902-1, 902-2, 902-3, a multi-laminate PWB 900 could be implemented with more or less than this number of substrates.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. A method of forming a plurality of interstitial resistors in a printed wiring board substrate, the printed wiring board substrate having a plurality of vias formed at least partially therethrough, the method comprising the steps of:
disposing a first mask over at least a portion of the printed wiring board substrate that leaves one or more first vias of the plurality of vias exposed and covers the remaining vias;
filling the first vias with an electrically resistive compound to thereby form one or more first interstitial resistors, each first interstitial resistor having a first electrical resistance value;
removing the first mask;
disposing a second mask over at least a portion of the printed wiring board substrate that leaves one or more second vias of the plurality of vias exposed and covers the remaining vias;
filling the second vias with an electrically resistive compound to thereby form one or more second interstitial resistors, each second interstitial resistor having a second electrical resistance value that differs from the first electrical resistance value; and
removing the second mask.

2. The method of claim 1, further comprising:
disposing a third mask over at least a portion of the printed wiring board substrate that leaves the first and second vias exposed and covers at least a portion of the remaining vias; and
depositing a conductive material over at least the first and second vias.

3. The method of claim 1, wherein the electrically resistive compounds disposed in the first and second vias differ in composition.

4. The method of claim 1, wherein the electrically resistive compounds disposed in the first and second vias are each carbon-based resistive inks.

5. The method of claim 1, wherein:
the first vias have a first diameter;
the second vias have a second diameter; and
the first diameter differs from the second diameter.

6. The method of claim 1, further comprising:
curing the resistive compound in the first vias after filling the first vias, and before filling the second vias; and
curing the resistive compound in the second vias after filling the second vias.

7. The method of claim 1, further comprising:
providing a second printed wiring board substrate having a plurality of vias formed at least partially therethrough;
disposing a third mask over the second printed wiring board substrate that leaves one or more third vias of the plurality of vias exposed and covers the remaining vias;
filling the third vias with an electrically resistive compound to thereby form one or more third interstitial resistors, each third interstitial resistor having a third electrical resistance value;
removing the third mask; and
joining the printed wiring board substrate to the second printed wiring board substrate to form a multi-laminate wiring board substrate assembly.

8. The method of claim 7, further comprising, before joining the first wiring board substrate to the second wiring board substrate:
disposing a fourth mask over the second printed wiring board substrate that exposes one or more fourth vias of the plurality of vias and covers the remaining vias;
filling the fourth vias with a fourth electrically resistive compound to thereby form one or more fourth interstitial resistors, each fourth interstitial resistor having a fourth electrical resistance value that differs from at least the third electrical resistance value; and
removing the fourth mask.

9. The method of claim 8, further comprising:
disposing a fifth mask over at least a portion of the second printed wiring board substrate that leaves the third and fourth vias exposed and covers at least a portion of the remaining vias; and
depositing a conductive material over at least the third and fourth vias.

10. The method of claim 7, wherein resistive compounds disposed in the first, second, third, and fourth vias differ in composition.

11. The method of claim 7, wherein the electrically resistive compounds disposed in the first, second, third, and fourth vias are each carbon-based resistive inks.

12. The method of claim 7, wherein:
the third electrical resistance value differs from either or both the first electrical resistance value and the second electrical resistance value; and
the fourth electrical resistance value differs from at least the third electrical resistance value.

13. The method of claim 7, wherein:
the first vias have a first diameter;
the second vias have a second diameter;
the third vias have a third diameter;
the fourth vias have a fourth diameter; and
the first diameter differs from one or more of the second, third, or fourth diameters.

14. A method of manufacturing a multi-laminate printed wiring board substrate assembly, comprising the steps of:
providing a first printed wiring board substrate having a plurality of vias formed at least partially therethrough;
disposing a first mask over the first printed wiring board substrate that leaves one or more first vias of the plurality of vias exposed and covers the remaining vias;
filling the first vias with an electrically resistive compound to thereby form one or more first interstitial resistors, each first interstitial resistor having a first electrical resistance value;
removing the first mask;
disposing a second mask over the first printed wiring board substrate that leaves one or more second vias of the plurality of vias exposed and covers the remaining vias;
filling the second vias with an electrically resistive compound to thereby form one or more second interstitial resistors, each second interstitial resistor having a second electrical resistance value that differs from the first electrical resistance value;
removing the second mask;
providing a second printed wiring board substrate having a plurality of vias formed at least partially therethrough;
disposing a third mask over the second printed wiring board substrate that leaves one or more third vias of the plurality of vias exposed and covers the remaining vias;
filling the third vias with an electrically resistive compound to thereby form one or more third interstitial resistors, each third interstitial resistor having a third electrical resistance value;
removing the third mask; and
joining the first printed wiring board substrate to the second printed wiring board substrate to form a multi-laminate wiring board substrate assembly.

15. The method of claim 14, further comprising, before coupling the first wiring board substrate to the second wiring board substrate:
disposing a fourth mask over the second printed wiring board substrate that exposes one or more fourth vias of the plurality of vias and covers the remaining vias;
filling the fourth vias with a fourth electrically resistive compound to thereby form one or more fourth interstitial resistors, each fourth interstitial resistor having a fourth electrical resistance value that differs from at least the third electrical resistance value; and
removing the fourth mask.

16. The method of claim 14, further comprising, before joining the first and second printed wiring board substrates:
disposing a fourth mask over at least a portion of the first printed wiring board substrate that leaves the first and second vias exposed and covers at least a portion of the remaining vias;
depositing a conductive material over at least the first and second vias;
disposing a fifth mask over at least a portion of the second printed wiring board substrate that leaves the third and fourth vias exposed and covers at least a portion of the remaining vias; and
depositing a conductive material over at least the third and fourth vias.

17. The method of claim 14, wherein resistive compounds disposed in the first, second, third, and fourth vias differ in composition.

18. The method of claim 14, wherein the electrically resistive compounds disposed in the first, second, third, and fourth vias are each carbon-based resistive inks.

19. The method of claim 14, wherein:
the third electrical resistance value differs from either or both the first electrical resistance value and the second electrical resistance value; and
the fourth electrical resistance value differs from at least the third electrical resistance value.

20. The method of claim 14, wherein:
the first vias have a first diameter;
the second vias have a second diameter;
the third vias have a third diameter;
the fourth vias have a fourth diameter; and
the first diameter differs from one or more of the second, third, or fourth diameters.
